(19) United States
(12) Patent Application Publication
(10) Pub. No.: US 2025/0226023 A1
(43) Pub. Date: Jul. 10, 2025

(54) MEMORY DEVICE, MEMORY SYSTEM, AND METHOD OF OPERATING THE MEMORY SYSTEM

(71) Applicant: SAMSUNG ELECTRONICS CO., LTD., Suwon-si (KR)

(72) Inventor: Sukhyun Lim, Suwon-si (KR)

(73) Assignee: SAMSUNG ELECTRONICS CO., LTD., Suwon-si (KR)

(21) Appl. No.: 19/009,445

(22) Filed: Jan. 3, 2025

(30) Foreign Application Priority Data
Jan. 4, 2024 (KR) 10-2024-0001670

(51) Int. Cl. G11C 11/406; G06F 3/06

(52) U.S. Cl. CPC G11C 11/40626; G06F 3/0616; G06F 3/0653; G06F 3/0673; G11C 11/40611; G11C 11/40615

(57) ABSTRACT

A memory device for performing refresh operations includes: a refresh management circuit configured to perform refresh operations on a memory device based on a refresh command received from the host; a counter configured to count a number of the refresh operations performed by the refresh management circuit; and a temperature information analysis module configured to obtain temperature information regarding a plurality of memory cells included in the memory device, wherein the refresh management circuit is further configured to: perform a predetermined number of the refresh operations during a first time period, based on determining that the predetermined number of the refresh operations are performed, receive the temperature information, and adjust a refresh rate of the memory device for a second time period based on the temperature information.

### CROSS-REFERENCE TO RELATED APPLICATION

This application is based on and claims priority under 35 U.S.C. § 119 to Korean Patent Application No. 10-2024-0001670, filed on Jan. 4, 2024, in the Korean Intellectual Property Office, the disclosure of which is incorporated by reference herein in its entirety.

### BACKGROUND

### 1. Field

The present disclosure relates to a memory device, a memory system, and a method of operating the memory device, and more particularly, to a memory device that adjusts a refresh rate according to temperature.

### 2. Description of Related Art

Memory devices including a volatile memory may periodically perform a refresh operation to preserve data. However, successive refresh operations may deteriorate the durability of memory cells.

Despite the above-stated problem, some memory devices may have a problem of performing a predetermined number of refresh operations during a predetermined time period without determining the optimal number of refresh operations according to temperature changes.

### SUMMARY

Provided is a memory device that sets an optimal refresh rate according to temperature.

Also provided is a method of maintaining the durability of memory cells in a memory device according to an embodiment and increasing the lifespan or reliability of the memory cells, by setting an optimal refresh rate according to temperature.

In accordance with an aspect of the disclosure, a memory device for performing refresh operations, the memory device includes: a refresh management circuit configured to perform refresh operations on a memory device based on a refresh command received from the host; a counter configured to count a number of the refresh operations performed by the refresh management circuit; and a temperature information analysis module configured to obtain temperature information regarding a plurality of memory cells included in the memory device, wherein the refresh management circuit is further configured to: perform a predetermined number of the refresh operations during a first time period, based on determining that the predetermined number of the refresh operations are performed, receive the temperature information, and adjust a refresh rate of the memory device for a second time period based on the temperature information.

In accordance with an aspect of the disclosure, a method of operating a memory device for performing refresh operations, includes: performing the refresh operations on the memory device based on a refresh command received from a host; counting a number the refresh operations which are performed; obtaining temperature information regarding a plurality of memory cells of the memory device; and based on determining that a predetermined number of the refresh operations are performed during a first time period, adjusting a refresh rate of the memory device for a second time period based on the temperature information.

In accordance with an aspect of the disclosure, a memory system for performing refresh operations on a memory device, the memory system including: a host configured to generate a plurality of commands corresponding to the memory device; a refresh management circuit configured to perform the refresh operations on the memory device based on a refresh command received from the host; a counter configured to count a number of the refresh operations performed by the refresh management circuit; and a temperature information analysis module configured to obtain temperature information regarding a plurality of memory cells included in the memory device, wherein the refresh management circuit is further configured to: perform a predetermined number of the refresh operations during a first time period, receive the temperature information based on the predetermined number of the refresh operations being performed, and adjust a refresh rate of the memory device for a second time period based on the temperature information.

### BRIEF DESCRIPTION OF DRAWINGS

Embodiments of the inventive concept will be more clearly understood from the following detailed description taken in conjunction with the accompanying drawings in which:

FIG. 1 is a block diagram showing a memory system according to an embodiment;

FIGS. 2 and 3 are block diagrams showing a memory device according to an embodiment;

FIG. 4 is a block diagram showing a refresh management circuit according to an embodiment;

FIG. 5 is a flowchart of a method of operating a memory system, according to an embodiment;

FIG. 6 is a flowchart of adjusting the refresh rate according to temperature information in a method of operating a memory system, according to an embodiment;

FIG. 7 is a flowchart illustrating a process for performing a refresh rate reset operation in a method of operating a memory system, according to an embodiment;

FIG. 8 is a graph illustrating a trend of a limit value of refresh operations which a memory device may perform during a time period according to temperature, according to an embodiment; and

FIG. 9 is a block diagram illustrating components of a memory device, according to an embodiment.

### DETAILED DESCRIPTION OF EMBODIMENTS

The following description is provided as an example only, and various alterations and modifications may be made to the described embodiments without departing from the scope of the disclosure. Accordingly, embodiments should not be construed as limited to the particular embodiments described below, and should be understood to include all changes, equivalents, and replacements within the scope of the disclosure.

As is traditional in the field, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the present scope. Further, the blocks, units and/or modules of the embodiments may be physically combined into more complex blocks, units and/or modules without departing from the present scope.

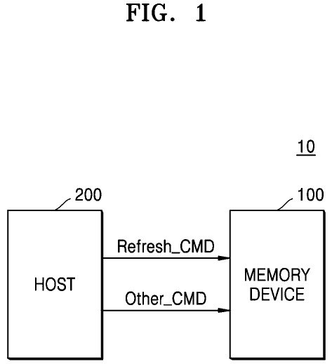

FIG. 1 is a block diagram showing a memory system 10 according to an embodiment.

Referring to FIG. 1, the memory system 10 according to an embodiment may include a memory device 100 and a host 200.

The memory device 100 according to an embodiment may receive a refresh command Refresh_CMD and other commands, for example a command Other_CMD from the host 200. The command Other_CMD according to an embodiment may be a command different from the refresh command Refresh_CMD and may be a command that instructs one or more of a plurality of operations of the memory device 100. For example, the command Other_CMD may include a read command or a write command for the memory device 100.

The memory device 100 according to an embodiment may receive a refresh command Refresh_CMD from the host 200 and perform a refresh operation based on the refresh command Refresh_CMD. A refresh operation according to an embodiment may refer to an operation to preserve data stored in memory cells included in the memory device 100 during a predetermined time period.

The memory device 100 according to an embodiment may be configured to determine the number of times that a refresh operation is performed, which may be referred to as determining a number of the refresh operations which are performed. For example, the memory device 100 may include a counter, determine the number the refresh operations which are performed, and determine whether a predetermined number of the refresh operations have been performed during a pre-determined time period. According to embodiments, the predetermined number may be a value set for each temperature section or temperature range, and may be determined or set when the memory device 100 is manufactured. However, embodiments are not limited thereto, and the predetermined number may be modified according to, for example, a user input or a command received from a host.

The memory device 100 according to an embodiment may determine temperature information regarding a plurality of memory cells. For example, the memory device 100 may determine temperature information regarding a plurality of memory cells in real time and adjust a refresh rate based on the temperature information. Temperature information regarding memory cells according to an embodiment may refer to information about a temperature of the memory cells, for example the average temperature of the memory cells. Also, adjusting the refresh rate according to an embodiment may refer to adjusting the number of times to perform refresh operations during a predetermined time period, or for example adjusting the number of refresh operations to be performed during the predetermined time period.

According to an embodiment, in response to the first temperature information, the memory device may determine a refresh rate as a first refresh rate corresponding to the first temperature information. In response to the second temperature information, the memory device may determine a refresh rate as a second refresh rate corresponding to the second temperature information. For example, when the second temperature information is higher than the first temperature information, the second refresh rate may be greater than the first refresh rate. In other words, the memory device may increase a refresh rate as a temperature increases.

According to an embodiment, in response to the first temperature information, the memory device may determine a refresh period as a first refresh period corresponding to the first temperature information. In response to the second temperature information, the memory device may determine a refresh period as a second refresh period corresponding to the second temperature information. For example, when the second temperature information is higher than the first temperature information, the second refresh period may be smaller than the first refresh period. In other words, the memory device may decrease a refresh period as a temperature increases.

For example, the memory device 100 may perform a refresh operation for a predetermined number of times during a first time period, receive temperature information when refresh operations are performed for the predetermined number of times, and adjust the refresh rate of a second time period based on received temperature information. In embodiments, performing the refresh operation a predetermined number of times may be referred to as performing a predetermined number of the refresh operations. The first time period and the second time period according to an embodiment may refer to time periods before and after a time period for performing the refresh operation, respectively. For example, the memory device 100 may perform a predetermined number of refresh operations during the first time period, adjust the refresh rate based on temperature information, and then perform refresh operations according to an adjusted refresh rate in the second time period.

The host 200 according to an embodiment may generate a plurality of commands for the memory device 100 and transmit generated commands to the memory device 100. For example, the host 200 may generate the refresh command Refresh_CMD and the command Other_CMD and transmit a generated refresh command Refresh_CMD and a generated command Other_CMD to the memory device 100. The refresh command Refresh_CMD according to an embodiment may be a signal instructing the memory device to perform a refresh operation on memory cells of the memory device 100. The command Other_CMD according to an embodiment is a command other than the refresh command Refresh_CMD and may be a command that instructs a plurality of operations of the memory device 100. For example, the command Other_CMD may include a read command or a write command for the memory device 100.

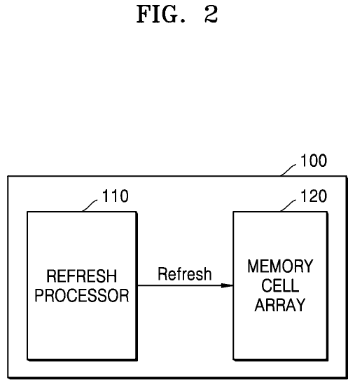

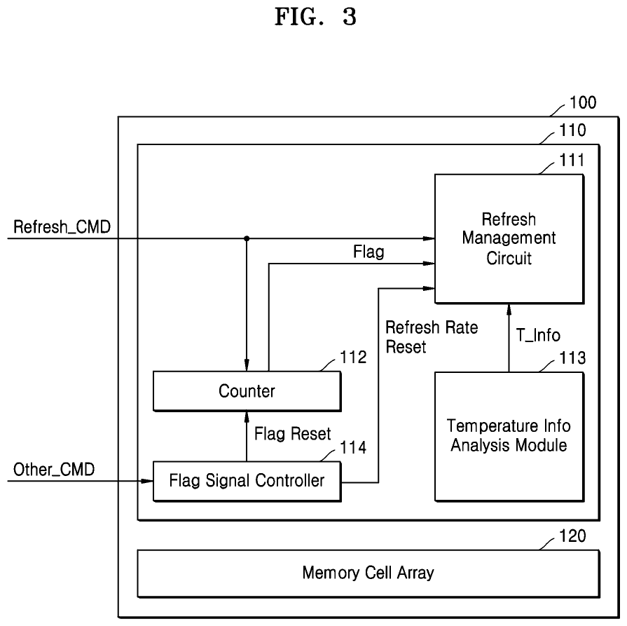

FIGS. 2 and 3 are block diagrams showing the memory device 100 according to an embodiment.

Referring to FIGS. 2 and 3, the memory device 100 according to an embodiment may include a refresh processor 110 and a memory cell array 120.

The refresh processor 110 according to an embodiment may transmit a refresh signal Refresh to the memory cell array 120 and may perform a refresh operation on the memory cell array 120. For example, the refresh processor 110 may perform a refresh operation on a plurality of memory cells included in the memory cell array 120. The refresh processor 110 according to an embodiment may perform a refresh operation based on the refresh command Refresh_CMD received from the host 200. A refresh operation according to an embodiment may refer to an operation to preserve data stored in memory cells included in the memory cell array 120 during a predetermined time period.

The refresh processor 110 according to an embodiment may be configured to determine the number of times that refresh operations are performed, or for example the number of refresh operations that are performed. For example, the refresh processor 110 may include a counter, determine the number refresh operations that are performed, and determine whether refresh operations have been performed for a predetermined number of times during a predetermined time period, or for example whether a predetermined number of refresh operations have been performed during the predetermined time period.

The refresh processor 110 according to an embodiment may determine temperature information regarding a plurality of memory cells. For example, the refresh processor 110 may determine temperature information regarding a plurality of memory cells in real time and adjust a refresh rate based on the temperature information. Temperature information regarding memory cells according to an embodiment may refer to information about a temperature of the memory cells, for example the average temperature of the memory cells. Also, adjusting the refresh rate according to an embodiment may refer to adjusting the number of times to perform refresh operations during a predetermined time period.

For example, the refresh processor 110 may perform a predetermined number of refresh operations during a first time period, receive temperature information when the predetermined number of refresh operations are performed, and adjust the refresh rate of a second time period based on received temperature information. For example, the refresh processor 110 according to an embodiment may perform a predetermined number of refresh operations during the first time period, adjust the refresh rate based on temperature information, and then perform refresh operations according to an adjusted refresh rate in the second time period.

The memory cell array 120 according to an embodiment may include a plurality of memory cells. The memory device 100 according to an embodiment may be a volatile memory. For example, the memory cell array 120 may include memory cells constituting a volatile memory device. The memory device 100 according to an embodiment may include a volatile memory such as static random access memory (SRAM), dynamic RAM (DRAM), or synchronous DRAM (SDRAM).

Referring further to FIG. 3, the refresh processor 110 according to an embodiment may include a refresh management circuit 111, a counter 112, a temperature information analysis module 113, or a flag signal controller 114.

The refresh management circuit 111 according to an embodiment may perform a refresh operation based on the refresh command Refresh_CMD received from the host 200. For example, the refresh management circuit 111 may receive temperature information T_Info regarding a plurality of memory cells in real time and adjust the refresh rate based on the temperature information T_Info. The refresh management circuit 111 according to an embodiment may perform a predetermined number of refresh operations in a predetermined time period, and, when the predetermined number of refresh operations is performed, the refresh management circuit 111 may adjust the refresh rate and perform refresh operations in a new time period. For example, the refresh management circuit 111 may perform a predetermined number of refresh operations during a first time period, receive the temperature information T_Info when the predetermined number of refresh operations are performed, and adjust the refresh rate of a second time period based on the received temperature information T_Info. For example, the refresh management circuit 111 according to an embodiment may perform a predetermined number of refresh operations during the first time period, adjust the refresh rate based on the temperature information T_Info, and then perform refresh operations according to an adjusted refresh rate in the second time period.

The refresh management circuit 111 according to an embodiment may be configured to stop a refresh operation when a flag signal Flag is activated. The flag signal Flag according to an embodiment may be a signal notifying or indicating that a reason for stopping a refresh operation has occurred in the refresh management circuit 111. The reason for stopping a refresh operation according to an embodiment may be any one of completion of a predetermined number of refresh operations, reception of the command Other_CMD other than a refresh command, or a change in the temperature information T_Info.

The refresh management circuit 111 according to an embodiment may stop a refresh operation when the command Other_CMD other than the refresh command Refresh_CMD is received. For example, when either a read command or a write command is received by the memory device 100, the refresh management circuit 111 may stop a refresh operation and reset the refresh rate for a new time period.

The refresh management circuit 111 according to an embodiment may stop a refresh operation when a predetermined number of refresh operations are performed. For example, the refresh management circuit 111 may perform a predetermined number of refresh operations, receive an activated flag signal Flag, and stop a refresh operation. After a refresh operation is stopped, the refresh management circuit 111 according to an embodiment may reset the refresh rate based on the temperature information T_Info and perform at least one refresh operation in a new time period.

When the temperature information T_Info is changed, the refresh management circuit 111 according to an embodiment may ignore the refresh command Refresh_CMD and adjust the refresh rate. For example, when a change in temperature information T_Info satisfies a predetermined criterion, the refresh management circuit 111 may adjust the refresh rate by ignoring the received refresh command Refresh_CMD. The refresh management circuit 111 according to an embodiment may ignore the refresh command Refresh_CMD at predetermined intervals. The predetermined criterion regarding a change in the temperature information T_Info according to an embodiment may be a criterion input when the memory device 100 is manufactured. However, embodiments are not limited thereto, and the predetermined criterion may be modified according to, for example, a user input or a command received from the host 200.

The counter 112 according to an embodiment may determine the number of refresh operations which are, or have been, performed, during any particular time period. The counter 112 may count the number of times of refresh operations. For example, the counter 112 may determine whether a predetermined number of refresh operations have been performed and may activate the flag signal Flag when the predetermined number of refresh operations have been performed. The counter 112 according to an embodiment may transmit the activated flag signal Flag to the refresh management circuit 111. When the flag signal Flag is received, the refresh management circuit 111 according to an embodiment may be configured to stop a refresh operation. The predetermined number according to an embodiment may be a value input when the memory device 100 is manufactured and may be changed for a predetermined time period according to temperature information. However, embodiments are not limited thereto, and the predetermined number may be modified according to, for example, a user input or a command received from the host 200.

The temperature information analysis module 113 according to an embodiment may determine the temperature information T_Info regarding a plurality of memory cells of a memory device. For example, the temperature information analysis module 113 may determine the temperature information T_Info regarding memory cells in real time and transmit determined temperature information T_Info to the refresh management circuit 111. When a change in temperature information T_Info satisfies a predetermined criterion, the refresh management circuit 111 according to an embodiment may adjust the refresh rate by ignoring the received refresh command Refresh_CMD. The refresh management circuit 111 according to an embodiment may ignore the refresh command Refresh_CMD at predetermined intervals. The predetermined criterion regarding a change in the temperature information T_Info according to an embodiment may be a criterion input when the memory device 100 is manufactured. However, embodiments are not limited thereto, and the predetermined criterion may be modified according to, for example, a user input or a command received from the host 200.

The flag signal controller 114 according to an embodiment may determine whether the command Other_CMD other than the refresh command Refresh_CMD is received. The flag signal controller 114 according to an embodiment may be configured to, when the command Other_CMD other than the refresh command Refresh_CMD is received, transmit a flag reset signal Flag Reset to the counter 112 and transmit a refresh rate reset signal refresh rate Reset to the refresh management circuit 111.

When the command Other_CMD other than the refresh command Refresh_CMD is received, the flag signal controller 114 according to an embodiment may transmit the flag reset signal Flag Reset to the counter 112. When the flag reset signal Flag Reset is received, the counter 112 may reset and generate the flag signal Flag and transmit the flag signal Flag to the refresh management circuit 111. The refresh management circuit 111 according to an embodiment may stop a refresh operation when the command Other_CMD other than the refresh command Refresh_CMD is received. For example, when either a read command or a write command is received by the memory device 100, the refresh management circuit 111 may stop a refresh operation and reset the refresh rate for a new time period based on the refresh rate reset signal refresh rate Reset.

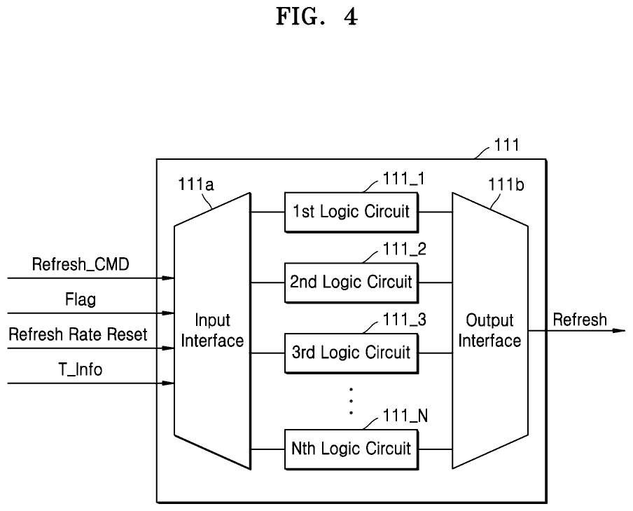

FIG. 4 is a block diagram showing the refresh management circuit 111 according to an embodiment.

Referring to FIG. 4, the refresh management circuit 111 according to an embodiment may include an input interface 111a, an output interface 111b, and a plurality of logic circuits 111_1, 111_2, 111_3, . . . , and 111_N.

The input interface 111a according to an embodiment may receive a plurality of signals. For example, the input interface 111a may receive at least one of the refresh command Refresh_CMD, the flag signal Flag, the refresh rate reset signal refresh rate Reset, and the temperature information T_Info. The input interface 111a according to an embodiment may receive the at least one of the flag signal Flag, the refresh rate reset signal refresh rate Reset, and the temperature information T_Info and transmit the refresh command Refresh_CMD to a logic circuit satisfying a predetermined criterion from among the plurality of logic circuits 111_1, 111_2, 111_3, . . . , and 111_N. For example, when the refresh rate of a first time period is set by a first logic circuit 111_1, a refresh operation is performed, and the temperature information T_Info is changed after a refresh operation of the first time period is performed, the input interface 111a may transmit the refresh command Refresh_CMD to a second logic circuit 111_2.

The plurality of logic circuits 111_1, 111_2, 111_3, . . . , and 111_N according to an embodiment may set a refresh rate according to a predetermined criterion.

The refresh rate determined by the first logic circuit 111_1 according to an embodiment may be 1:1, and the refresh rate determined by the second logic circuit 111_2 may be 2:1. The refresh rate according to an embodiment may refer to the rate between the refresh command Refresh_CMD and the number of times the refresh operation is performed. For example, when the refresh rate determined by the first logic circuit 111_1 is 1:1, the first logic circuit 111_1 may perform a number of refresh operations that is equal to the number of times that the refresh command Refresh_CMD is received. In another example, when the refresh rate determined by the second logic circuit 111_2 is 2:1, the second logic circuit 111_2 may perform one refresh operation based on the refresh command Refresh_CMD being received twice. Accordingly, the refresh rate determined by the second logic circuit 111_2 according to an embodiment is 2:1, the second logic circuit 111_2 may ignore the refresh command Refresh_CMD at the rate of 2:1 (e.g., may ignore every other refresh command Refresh_CMD). In another example, when the refresh rate determined by a third logic circuit 111_3 is 3:1, the third logic circuit 111_3 may perform one refresh operation every based on the refresh command Refresh_CMD being received three times. When the refresh rate determined by the third logic circuit 111_3 according to an embodiment is 3:1, the third logic circuit 111_3 may ignore the refresh command Refresh_CMD at the rate of 3:1 (e.g., may ignore two out of every three refresh commands Refresh_CMD).

However, refresh rates determined by the plurality of logic circuits 111_1, 111_2, 111_3, . . . , and 111_N are not limited thereto, and various rates may be determined by the plurality of logic circuits 111_1, 111_2, 111_3, . . . , and 111_N. For example, when the refresh rate determined by an N-th logic circuit 111_N is N:1, the N-th logic circuit 111_N may perform one refresh operation every time the refresh command Refresh_CMD is received N times. When the refresh rate determined by the N-th logic circuit 111_N according to an embodiment is N:1, the N-th logic circuit 111_N may ignore the refresh command Refresh_CMD at the rate of N:1 (e.g., may ignore (N-1) out of every N refresh commands Refresh_CMD).

The output interface 111b according to an embodiment may output the refresh signal Refresh including refresh rate information set by any one of the plurality of logic circuits 111_1, 111_2, 111_3, . . . , and 111_N. For example, the output interface 111b may transmit the refresh signal Refresh including refresh rate information set by any one of the plurality of logic circuits 111_1, 111_2, 111_3, . . . , and 111_N to the memory cell array 120 of FIG. 2 or FIG. 3.

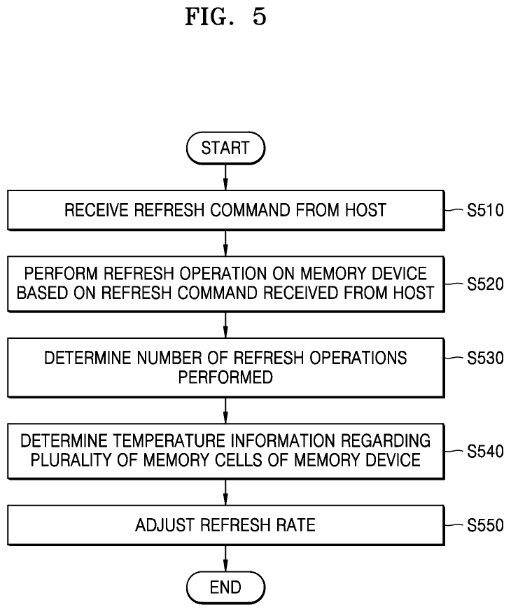

FIG. 5 is a flowchart of a method of operating a memory system, according to an embodiment.

Referring to FIGS. 1 and 5, the memory device 100 according to an embodiment may receive the refresh command Refresh_CMD from the host 200 at operation S510.

When the refresh command Refresh_CMD is received, the memory device 100 according to an embodiment may perform a refresh operation on the memory device 100 based on the refresh command Refresh_CMD received from the host 200 at operation S520. A refresh operation according to an embodiment may refer to an operation to preserve data stored in memory cells included in the memory device 100 during a predetermined time period.

When a refresh operation is performed, the memory device 100 according to an embodiment may determine the number of times that refresh operations are performed (e.g., the number of refresh operations that are performed) at operation S530.

The memory device 100 according to an embodiment may be configured to determine the number of refresh operations that are performed. For example, the memory device 100 may include a counter, determine the number of refresh operations that are performed, and determine whether a predetermined number of refresh operations have been performed during a predetermined time period.

As a result of determining the number of refresh operations that are performed, when it is determined that the predetermined number of refresh operations have been performed, the memory device 100 according to an embodiment may determine temperature information regarding a plurality of memory cells of the memory device 100 at operation S540.

The refresh processor 110 according to an embodiment may be configured to determine the number of times that refresh operations are performed. For example, the refresh processor 110 may include a counter, determine the number of refresh operations that are performed, and determine whether a predetermined number of refresh operations have been performed during a predetermined time period. The predetermined time period according to an embodiment may be a time period determined when the memory device 100 is manufactured. A predetermined number according to an embodiment may be a value set for each temperature section when the memory device 100 is manufactured. However, embodiments are not limited thereto, and at least one of the predetermined time period and the predetermined number may be modified according to, for example, a user input or a command received from the host 200.

When temperature information regarding a plurality of memory cells is determined, the memory device 100 according to an embodiment may adjust the refresh rate at operation S550.

The memory device 100 according to an embodiment may determine temperature information regarding a plurality of memory cells. For example, the memory device 100 may determine temperature information regarding a plurality of memory cells in real time and adjust a refresh rate based on the temperature information. Temperature information regarding memory cells according to an embodiment may refer to information about a temperature of the memory cells, for example the average temperature of the memory cells. Also, adjusting the refresh rate according to an embodiment may refer to adjusting the number of times to perform refresh operations during a predetermined time period.

For example, the memory device 100 may perform a predetermined number of refresh operations during a first time period, receive temperature information when the predetermined number of refresh operations are performed, and adjust the refresh rate of a second time period based on received temperature information. The first time period and the second time period according to an embodiment may refer to time periods before and after a time period for performing at least one refresh operation, respectively. For example, the memory device 100 may perform a predetermined number of refresh operations during the first time period, adjust the refresh rate based on temperature information, and then perform refresh operations according to an adjusted refresh rate in the second time period.

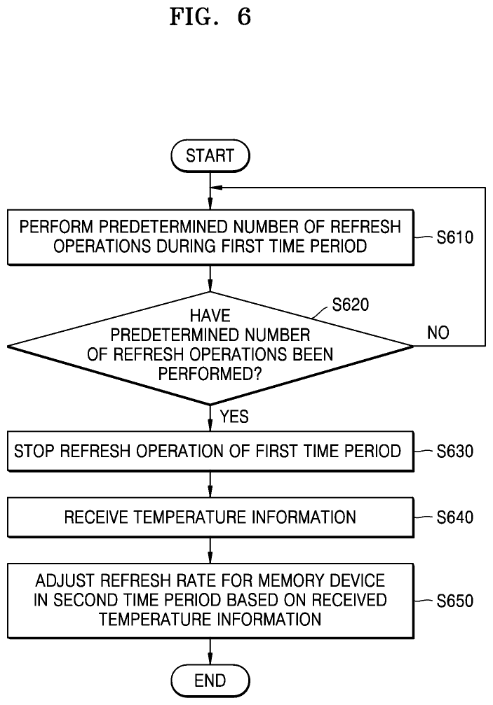

FIG. 6 is a flowchart of adjusting the refresh rate according to temperature information in a method of operating a memory system, according to an embodiment.

Referring to FIGS. 2, 3, and 6, the memory device 100 according to an embodiment may perform a predetermined number of refresh operations during a first time period at operation S610.

For example, the memory device 100 may perform a predetermined number of refresh operations during a first time period, receive temperature information when the predetermined number of refresh operations are performed, and adjust the refresh rate of a second time period based on received temperature information. The first time period and the second time period according to an embodiment may refer to time periods before and after a time period for performing at least one refresh operation, respectively. For example, the memory device 100 may perform a predetermined number of refresh operations during the first time period, adjust the refresh rate based on temperature information, and then perform refresh operations according to an adjusted refresh rate in the second time period.

The memory device 100 according to an embodiment may determine whether a predetermined number of refresh operations have been at operation S620. The predetermined number according to an embodiment may be a value set for each temperature section when the memory device 100 is manufactured. However, embodiments are not limited thereto, and the predetermined number may be modified according to, for example, a user input or a command received from the host 200.

When it is determined that the predetermined number of refresh operations have been completed, the memory device 100 according to an embodiment may stop a refresh operation of the first time period at operation S630. The memory device 100 according to an embodiment may be configured to stop a refresh operation when the flag signal Flag is activated. The flag signal Flag according to an embodiment may be a signal notifying or indicating that a reason for stopping a refresh operation has occurred in the memory device 100. The reason for stopping a refresh operation according to an embodiment may be any one of completion of a predetermined number of refresh operations, reception of the command Other_CMD other than a refresh command, or a change in the temperature information T_Info.

However, when it is determined that the predetermined number of refresh operations have not been performed, the memory device 100 according to an embodiment may perform refresh operations until the refresh operations of the first time period are completed.

When the refresh operations of the first time period are stopped, the memory device 100 according to an embodiment may receive the temperature information T_Info at operation S640. Temperature information regarding memory cells according to an embodiment may refer to information about a temperature of the memory cells, for example the average temperature of the memory cells.

When temperature information is received, the memory device 100 according to an embodiment may adjust the refresh rate for the memory device 100 in the second time period based on the received temperature information at operation S650. Adjusting the refresh rate according to an embodiment may refer to adjusting the number of refresh operations to be performed during a predetermined time period.

For example, the memory device 100 may receive temperature information T_Info regarding a plurality of memory cells in real time and adjust the refresh rate based on the temperature information T_Info. The memory device 100 according to an embodiment may perform a predetermined number of refresh operations in a predetermined time period, and, when the predetermined number of refresh operations is performed, the memory device 100 may adjust the refresh rate and perform refresh operations in a new time period. For example, the memory device 100 may perform a predetermined number of refresh operations during a first time period, receive the temperature information T_Info when the predetermined number of refresh operations are performed, and adjust the refresh rate of a second time period based on the received temperature information T_Info. For example, the memory device 100 according to an embodiment may perform a predetermined number of refresh operations during the first time period, adjust the refresh rate based on the temperature information T_Info, and then perform refresh operations according to an adjusted refresh rate in the second time period.

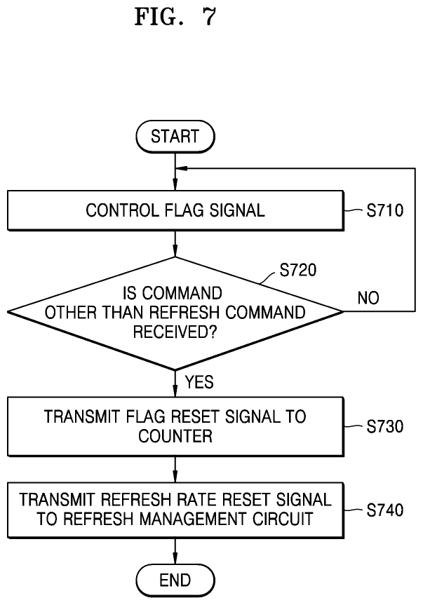

FIG. 7 is a flowchart illustrating a process for performing a refresh rate reset operation in a method of operating a memory system, according to an embodiment.

Referring to FIGS. 2, 3, and 7, the memory device 100 according to an embodiment may control the flag signal Flag at operation S710.

The memory device 100 according to an embodiment may determine the number of times that refresh operations are performed. For example, the memory device 100 may determine whether a predetermined number of refresh operations have been performed and may activate the flag signal Flag when the predetermined number of refresh operations have been performed. The memory device 100 according to an embodiment may transmit the activated flag signal Flag to the refresh management circuit 111. When the flag signal Flag is received, the refresh management circuit 111 according to an embodiment may be configured to stop a refresh operation. The predetermined number of times to perform refresh operations according to an embodiment may be a value input when the memory device 100 is manufactured and may be changed according to a predetermined time period according to temperature information. However, embodiments are not limited thereto, and the predetermined number may be modified according to, for example, a user input or a command received from the host 200.

The memory device 100 according to an embodiment may determine whether the command Other_CMD other than the refresh command Refresh_CMD is received at operation S720.

The command Other_CMD according to an embodiment is a command other than the refresh command Refresh_CMD and may be a command that instructs a plurality of operations of the memory device 100. For example, the command Other_CMD may include a read command or a write command for the memory device 100.

When it is determined that the command Other_CMD other than the refresh command Refresh_CMD is received, the memory device 100 according to an embodiment may transmit the flag reset signal Flag Reset to the counter 112 at operation S730. Also, when it is determined that the command Other_CMD other than the refresh command Refresh_CMD is received, the memory device 100 according to an embodiment may transmit the refresh rate reset signal Refresh Rate Reset to the refresh management circuit 111 at operation S740.

The memory device 100 according to an embodiment may determine whether the command Other_CMD other than the refresh command Refresh_CMD is received. The memory device 100 according to an embodiment may be configured to, when the command Other_CMD other than the refresh command Refresh_CMD is received, transmit a flag reset signal Flag Reset to the counter 112 and transmit a refresh rate reset signal refresh rate Reset to the refresh management circuit 111.

When the command Other_CMD other than the refresh command Refresh_CMD is received, the memory device 100 according to an embodiment may transmit the flag reset signal Flag Reset to the counter 112. When the flag reset signal Flag Reset is received, the counter 112 may reset and generate the flag signal Flag and transmit the flag signal Flag to the refresh management circuit 111. The refresh management circuit 111 according to an embodiment may stop a refresh operation when the command Other_CMD other than the refresh command Refresh_CMD is received. For example, when either a read command or a write command is received by the memory device 100, the refresh management circuit 111 may stop a refresh operation and reset the refresh rate for a new time period based on the refresh rate reset signal refresh rate Reset.

However, when it is determined that the command Other_CMD other than the refresh command Refresh_CMD has not been received, the memory device 100 according to an embodiment may continue to perform a refresh operation.

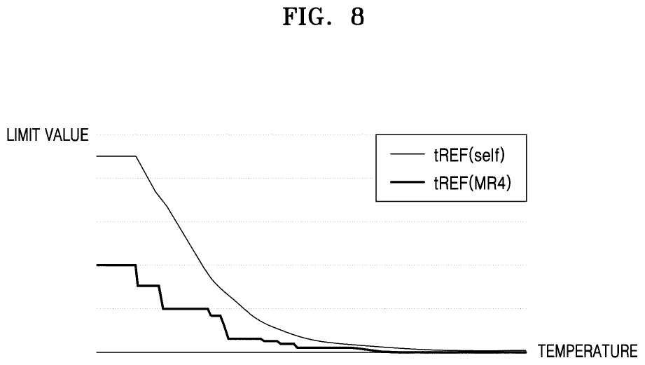

FIG. 8 is a graph illustrating a trend of a limit value of refresh operations to be performed during a refresh operation time period according to temperature, according to an embodiment.

In the graph according to the embodiment of FIG. 8, the x-axis represents temperature, and the y-axis represents the maximum refresh operation acceptance limit of the memory device 100 according to temperature. The y-axis represents the refresh cycle according to temperature. According to an embodiment, the memory device 100 may perform an auto refresh operation in response to a refresh command received from the host 200 (or a memory controller). The memory device 100 may perform a self-refresh operation. The memory device 100 may perform a self-refresh operation without intervention of the host 200. The memory device 100 may perform a self-refresh operation even when a refresh command is not received from the host 200.

A refresh period [tREF (self)] corresponding to a self-refresh operation Self according to an embodiment may to have a higher limit than a refresh period [tREF(MR4)] corresponding to a refresh operation MR4 performed based on a predetermined criterion. In other words, in terms of a refresh period according to temperature, the refresh period [tREF (self)] corresponding to the self-refresh operation Self according to an embodiment may have a higher limit than the refresh period [REF(MR4)] corresponding to the refresh operation MR4 performed based on a predetermined criterion. For example, at the same temperature, the refresh cycle [tREF (self)] of the self-refresh operation may be longer than the refresh cycle [tREF(MR4)] of the auto-refresh operation.

Referring to FIG. 8, when the memory device 100 according to an embodiment successively performs the refresh operation MR4 performed based on a predetermined criterion, the durability of the memory cells of the memory device 100 may converge to be similar as the durability of the memory cells of the memory device 100 corresponding to the self-refresh operation Self. According to an embodiment, the memory device 100 according to an embodiment may adjust a refresh rate or a refresh period based on the temperature in response to reception of a pre-set number of refresh commands or more. For example, at a first temperature, the memory device 100 may perform a refresh operation in a first refresh period in response to a refresh command. At the first temperature, the memory device 100 may perform a refresh operation in a second refresh period in response to reception of a pre-set number of refresh commands or more. The second refresh period may be longer than the first refresh period. Therefore, the memory device 100 may reduce current consumption. The memory device 100 according to an embodiment may maintain the durability of memory cells by performing the refresh operation based on a predetermined criterion according to temperature.

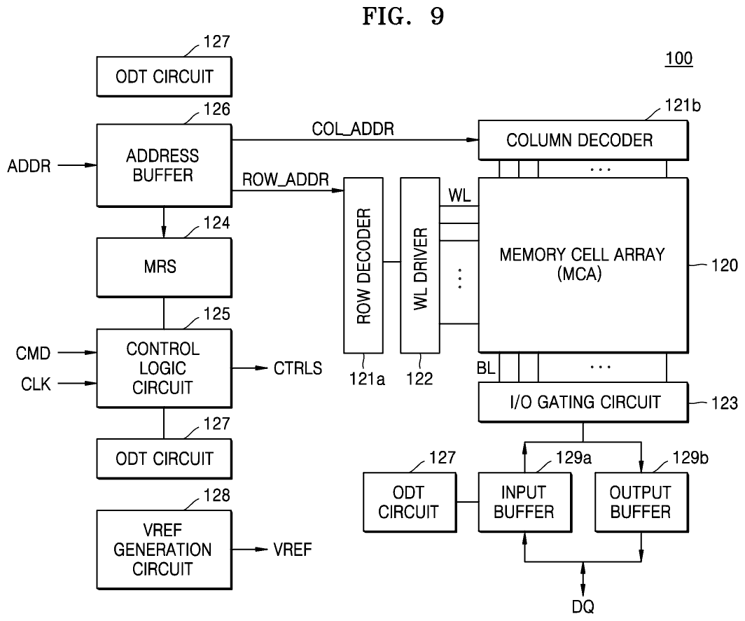

FIG. 9 is a block diagram illustrating components of a memory device, according to an embodiment.

Referring to FIG. 9, the memory device 100 may include the memory cell array 120, a row decoder 121a, a word line driver 122, a column decoder 121b, an input/output gating circuit 123, an MRS 124, a control logic circuit 125, an address buffer 126, an ODT circuit 127, a reference voltage generating circuit 128, a data input buffer 129a, and a data output buffer 129b.

The memory cell array 120 may include a plurality of memory cells provided in the form of a matrix including rows and columns. The memory cell array 120 may include a plurality of word lines WL and a plurality of bit lines BL connected to memory cells. The plurality of word lines WL may be connected to memory cells in rows, and the plurality of bit lines BLm may be connected to memory cells in columns.

The row decoder 121a may select any one of the word lines WL connected to the memory cell array 120. The row decoder 121a may decode a row address ROW_ADDR received from the address buffer 126, select any one word line WL corresponding to the row address ROW_ADDR, and connect a selected word line WL to the word line driver 122 that activates the selected word line WL. The column decoder 121b may select predetermined bit lines BL from among the bit lines BL of the memory cell array 120. The column decoder 121b may generate a column select signal CSL by decoding a column address COL_ADDR received from the address buffer 126 and connect bit lines BL selected by the column select signal CSL to the input/output gating circuit 123. The input/output gating circuit 123 may include read data latches for storing read data of the bit lines BL selected by the column select signal CSL and a write driver for writing write data to the memory cell array 120. Read data stored in the read data latches of the input/output gating circuit 123 may be provided to the data bus through the data output buffer 129b. Write data may be applied to the memory cell array 120 through the data input buffer 129a connected to the data bus and through the write driver of the input/output gating circuit 123.

The control logic circuit 125 may receive a clock signal CLK and a command CMD and generate control signals CTRLS for controlling an operation timing and/or a memory operation of the memory cell array 120. The control logic circuit 125 may use the control signals CTRLS to read data from the memory cell array 120 and to write data to the memory cell array 120.

The MRS 124 may store information used by the control logic circuit 125 to configure the operation of the memory device 100 to set an operating condition for the memory device 100. The MRS 124 may include a register that stores parameter codes for various operation parameters and control parameters used to set an operating condition of the memory device 100. A parameter code may be received by the memory device 100 through the command/address bus. The control logic circuit 125 provides control signals CTRLS to circuits of the memory device 100 to operate as set by operation parameters and control parameters stored in the MRS 124.

The ODT circuit 127 may provide termination resistance when being enabled for the command/address bus and/or the data bus. The termination resistance may improve the SI of signals received through a bus. The enabling of the ODT circuit 127 and the magnitude of the termination resistance provided to a bus may be set by recording a suitable parameter code to the MRS 124.

The reference voltage generating circuit 128 may provide a reference voltage VREF used by circuits of the memory device 100. For example, the reference voltage VREF may be used by the control logic circuit 125 for comparison with a voltage of a signal received from a command bus to determine a logic value of the signal. The reference voltage VREF and/or the range of the reference voltage VREF may be set by recording a reference voltage operation parameter code in the MRS 124.

The data input buffer 129a may provide write data received through a data bus to the input/output gating circuit 123.

The data output buffer 129b may provide read data stored in read data latches of the input/output gating circuit 123 to a memory controller through the data bus.

While some embodiments are particularly shown and described herein, it will be understood that various changes in form and details may be made therein without departing from the spirit and scope of the following claims.

What is claimed is:

1. A memory device for performing refresh operations, the memory device comprising:
a refresh management circuit configured to perform refresh operations on the memory device based on a refresh command received from a host;
a counter configured to count a number of the refresh operations performed by the refresh management circuit; and
a temperature information analysis module configured to obtain temperature information regarding a plurality of memory cells included in the memory device,
wherein the refresh management circuit is further configured to:
perform a predetermined number of the refresh operations during a first time period,
based on determining that the predetermined number of the refresh operations are performed, receive the temperature information, and
adjust a refresh rate of the memory device for a second time period based on the temperature information.

2. The memory device of claim 1, wherein the counter is further configured to activate a flag signal based on determining that the predetermined number of the refresh operations are performed, and
wherein the refresh management circuit is further configured to stop performing the refresh operations based on the flag signal being activated.

3. The memory device of claim 1, wherein the refresh management circuit is further configured to stop performing the refresh operations based on a command other than the refresh command being received.

4. The memory device of claim 3, wherein the refresh management circuit is further configured to reset the refresh rate after the refresh operations are stopped.

5. The memory device of claim 1, wherein the refresh management circuit is further configured to ignore the refresh command and adjust the refresh rate based on a change in the temperature information.

6. The memory device of claim 1, further comprising a flag signal controller configured to determine whether a command other than the refresh command is received.

7. The memory device of claim 6, wherein, based on the command being received, the flag signal controller is further configured to transmit a flag reset signal to the counter, and transmit a refresh rate reset signal to the refresh management circuit.

8. A method of operating a memory device for performing refresh operations on the memory device, the method comprising:
performing the refresh operations on the memory device based on a refresh command received from a host;
counting a number the refresh operations which are performed;
obtaining temperature information regarding a plurality of memory cells of the memory device; and
based on determining that a predetermined number of the refresh operations are performed during a first time period, adjusting a refresh rate of the memory device for a second time period based on the temperature information.

9. The method of claim 8, wherein the counting the number of the refresh operations comprises activating a flag signal based on determining that the predetermined number of the refresh operations are performed, and
wherein the refresh operations are stopped based on the flag signal being activated.

10. The method of claim 8, wherein the refresh operations are stopped based on a command other than the refresh command being received.

11. The method of claim 10, wherein the refresh rate is reset after the refresh operations are stopped.

12. The method of claim 8, wherein the refresh command is ignored and the refresh rate is adjusted based on a change in the temperature information.

13. The method of claim 8, further comprising: based on a command other than the refresh command being received, controlling a flag signal by transmitting a flag reset signal to a counter and transmitting a refresh rate reset signal to a refresh management circuit.

14. A memory system for performing refresh operations on a memory device, the memory device comprising:
a host configured to generate a plurality of commands corresponding to the memory device;
a refresh management circuit configured to perform the refresh operations on the memory device based on a refresh command received from the host;
a counter configured to count a number of the refresh operations performed by the refresh management circuit; and
a temperature information analysis module configured to obtain temperature information regarding a plurality of memory cells included in the memory device,
wherein the refresh management circuit is further configured to:
perform a predetermined number of the refresh operations during a first time period,
receive the temperature information based on the predetermined number of the refresh operations being performed, and
adjust a refresh rate of the memory device for a second time period based on the temperature information.

15. The memory system of claim 14, wherein the counter is further configured to activate a flag signal based on the predetermined number of the refresh operations being performed, and
wherein the refresh management circuit is further configured to stop the refresh operations based on the flag signal being activated.

16. The memory system of claim 14, wherein the refresh management circuit is further configured to stop the refresh operations based on a command other than the refresh command being received.

17. The memory system of claim 16, wherein the refresh management circuit is further configured to reset the refresh rate after the refresh operations are stopped.

18. The memory system of claim 14, wherein the refresh management circuit is further configured to ignore the refresh command and adjust the refresh rate based on a change in the temperature information.

19. The memory system of claim 14, further comprising a flag signal controller configured to determine whether a command other than the refresh command is received.

20. The memory system of claim 19, wherein based on the command being received, the flag signal controller is further configured to transmit a flag reset signal to the counter and transmit a refresh rate reset signal to the refresh management circuit.
